(19) United States
(12) Patent Application Publication
(10) Pub. No.: US 2010/0283484 A1
(43) Pub. Date: Nov. 11, 2010

(54) Method and Apparatus for Localizing an Object in the Body

(76) Inventors: Richard J. Cohen, Chestnut Hill, MA (US); Maya Barley, Somerville, MA (US)

Correspondence Address: CHOATE, HALL & STEWART LLP, TWO INTERNATIONAL PLACE, BOSTON, MA, 02110, US

(21) Appl. No.: 12/445,668

(22) PCT Filed: Oct. 3, 2007
(86) PCT No.: PCT/US07/80250

§ 371 Date: Jul. 19, 2010

Related U.S. Application Data
(60) Provisional application No. 60/852,093, filed on Oct. 16, 2006.

(51) Int. Cl. G01R 27/28

(52) U.S. Cl. 324/649

(57) ABSTRACT

Method and apparatus for real-time, 3-D image guidance of invasive surgical diagnostic tools and therapy. In this method, the 3-D distribution of electrical conductivity of the surgical region of interest are derived using images derived from magnetic resonance imaging (MRI) X-Ray Computed Tomography (CT) or other techniques. Current flows and voltages within the region due to applied currents from body surface electrodes at defined locations are simulated using a finite element method. During the surgical procedure, electrodes are placed at the same locations, and the surgical instrument is inserted into the region. By matching the potentials measured by the instrument to the simulated potentials, the instrument location may be identified in real-time.

This application claims priority to provisional application Ser. No. 60/852,093, filed Oct. 16, 2006, the contents of which are incorporated herein by reference.

### BACKGROUND TO THE INVENTION

This invention relates to method and apparatus for the image guidance of invasive surgical and diagnostic tools, including but not limited to such procedures as organ biopsies, device implantation, and radiofrequency ablation.

In many applications in medicine it is desirable to localize an object in the body. For example, many procedures require the introduction of a catheter or needle into the body in order to deliver therapy in a localized area. One may also wish to introduce a catheter via an artery or vein into the heart in order to deliver radiofrequency energy and ablate the site of origin of an arrhythmia. Or one may wish to introduce drugs, hypothermia, or radioactive material into a localized area in the body in order to treat a tumor, infection, or an anatomical abnormality. Catheters are often placed inside the body in order to perform procedures such as endoscopies and colonoscopies, and are also used in minimally-invasive surgeries. Improvements in the precision of localizing the object in the body will greatly enhance the effectiveness of these medical procedures.

Minimally-invasive (MI) surgery allows surgeons to diagnose and treat conditions with a minimum of the pain, discomfort, disability and morbidity that are more frequently due to the trauma involved in getting access to the surgical site than the procedure itself. For example, following a cholecystectomy, the need for hospitalization was not related to the removal of the gallbladder but rather was necessary because of the pain from the trauma to the abdominal wall caused by the incision to gain access to the gallbladder. [1] Numbers in square brackets refer to the references appended hereto, the contents of all of which are incorporated herein by reference. The concept of MI surgery has existed for almost a century [2], but the technology to make it possible on a wide scale was only developed in the late 20^{th} century. [3] Minimally-invasive surgical techniques are now used in many specialties including general surgery, plastic surgery, urology, thoracic surgery and cardiac surgery.

Satisfactory visualization of the instruments in relation to the surgical site has often been the rate-limiting step in the development of new minimally-invasive treatments and diagnostic tools. Currently, many surgeries are done under x-ray, ultrasound or (infrequently) MRI guidance. However, x-ray and fluoroscopy lead to significant radiation exposure to the patient and surgeon [4]. Furthermore, the carcinogenic potential of ionizing radiation does not allow for real-time monitoring of the instrument location, and the surgeon must instead capture “snap-shots” of the surgical site. Also, only 2-D projection images are available which makes it difficult to relate the position of instruments to the 3-D anatomy of the patient. [5] Lastly, some soft-tissue structures and lesions are not easily visible on x-ray. [6]

Ultrasonographic guidance, on the other hand, provides real-time positional monitoring and does not entail potentially dangerous radiation exposure. Ultrasound equipment is also widely available. However, sonographically-guided surgery (especially in the case of surgical biopsy) often requires excellent hand-eye coordination because of the need to hold both the surgical instrument and the ultrasound transducer. [6] Furthermore, sonography can in some cases only image a subset of lesions. [7] As with x-ray guidance, the images are 2-D projections of 3-D instrument movement, potentially leading to inaccurate positioning. 3-D ultrasound imaging has recently been developed. Although excellent stereoscopically-displayed 3-D ultrasound images of breast tumors and cardiac structures have been demonstrated, image reconstruction cannot be done in real-time, and therefore this is not yet a viable guidance technology. [8]

Guidance under MRI imaging, on the other hand, is real-time, 3-D, of high resolution, and is usually the most sensitive imaging modality for defining soft-tissue anatomic locations and lesion boundaries. [9] However, because the MRI imaging equipment must be present in the procedure room, such procedures are highly expensive and are limited to those hospitals or clinics with the necessary resources. MRI imaging equipment is also bulky and unwieldy, restricting the space available to the surgical team. Furthermore, the large magnetic fields require the use of special surgical instruments. [10] Therefore, a surgical guidance system is needed with 3-D imaging capability, sensitivity, real-time monitoring potential, safety, and low cost.

Breast biopsy is an excellent example of a common minimally-invasive procedure for which improvements in guidance mechanisms could lead to significant increases in accurate diagnosis and tumor excision. Breast cancer is the second-leading cause of death from cancer in American women. Breast cancer is diagnosed through biopsy of a suspicious lesion normally detected on palpation or through routine screening. Mammography is the only screening test for breast cancer that has been extensively evaluated. Approximately one-quarter of all breast cancers occur in women below the age of 50, in younger patients the density of the breast parenchyma reduces the ability of mammography to detect lesions. Breast biopsy conducted under stereotactic imaging is also of reduced accuracy in this subset of patients. Therefore in this patient sub-group, the prognosis is poor.

Contrast-enhanced MRI, on the other hand, has a sensitivity of greater than 90% in the detection of breast cancer. [11] It is sensitive to small lesions and can successfully image dense breast tissue. Therefore, MRI is often used as a breast-cancer screening tool alongside mammography in high-risk younger women. [12] However, breast biopsy under MRI guidance suffers from the drawbacks detailed above, and is only used in high-risk women whose lesions cannot be imaged with any other imaging modality. A biopsy-guidance system that combines the sensitivity and 3-D imaging capability of MRI with the real-time monitoring potential and safety of ultrasound, and the low cost of sonography would be invaluable.

Radio-Frequency Ablation (RFA) of cardiac arrhythmias requires more complex guidance systems, due to the complexity of the cardiac structure, the movement of the beating heart, and the risk of life-threatening injury. Several novel guidance systems have recently been developed; however, each of these has significant drawbacks. Improvements in guidance technology could lead to significant improvements in the accuracy of ablation and in the standard of living of those with ventricular arrhythmias.

One recently developed RFA guidance technology, CARTO, uses a special catheter to generate 3-D electroanatomic cardiac maps, and is now widely used in RFA procedures. A device external to the patient's body emits a very low magnetic field that is detected at the tip of the mapping and ablation catheter, and is used to sense its location and orientation relative to the magnetic field emitter. The catheter tip simultaneously stimulates the cardiac tissue and records the resulting local electrocardiograms. The amplitude of the local electrograms during sinus mapping, and the site at which they were recorded, are displayed in a 3-D electro-anatomical map that clearly delineates scar tissue. The catheter tip is also displayed; the display is R-wave gated so that movement due to heart motion is cancelled. CARTO has several drawbacks. The degree of resolution of the endocardial map is limited by the time available to acquire data points (upwards of 550 electrograms are required during ventricular mapping). CARTO can only approximate the cardiac anatomy because the images it creates are reconstructed from a limited number of endocardial mapping points. Therefore it cannot replicate the detailed cardiac morphology as displayed with computed tomography (CT) or magnetic resonance imaging (MRI).

CartoMerge is a newly FDA-approved technology that aligns a pre-procedural cardiac CT or MRI image with the electroanatomic maps and real-time data generated by a traditional CARTO system. The system tracks and displays the estimated real-time catheter tip location and orientation within the true cardiac anatomy. [13] This technology allows an individualized approach to a variety of anatomic abnormalities, and could facilitate complex clinical ablation procedures in which anatomic guidance would be invaluable. However, this technology suffers from a number of drawbacks that exist in addition to those described for the CARTO system alone. The accuracy of image registration (the method by which CARTO data is mapped to the MRI image) is highly dependent on the location of the landmarks used in the registration and on the number of endocardial mapping points collected by the CARTO system. Furthermore, small errors in the acquisition of registration points may introduce significant registration error, especially at mapping points far from the registration landmarks.

The RealTime Position Management® system from Cardiac Pathways uses ultrasound to monitor the absolute position of the electrodes, ablation catheter, and the cardiac tissue itself. Like the CARTO system, it analyzes the electrical characteristics of the tissue at individual points. This information is then overlaid with the ultrasound images to create an electroanatomic map. Because the system indicates catheter position during mapping and allows recall of previous catheter positions, the catheter can be guided to a point on the map [14]. However, frequent failure of the ultrasound transducers, requiring catheter replacement, is a significant drawback. Furthermore, ultrasound has a far-lower resolution than either MRI or CT. Consequently, the electroanatomic map lacks fine detail that would assist in precise placement of the ablation catheter.

The LocaLisa positioning system is a non-fluoroscopic catheter positioning system that allows a conventional catheter to be located in three dimensions. Three orthogonal electric fields are generated across the body by sets of skin electrodes. For calibration purposes, the electrical field strength due to each applied current within the cardiac chamber of interest is first calculated. This is done automatically by measuring the amplitude difference for 3 different spatial orientations of the catheter tip between neighboring electrode pairs with a known inter-electrode distance. [15] Following calibration, the catheter can be freely moved within the chamber. The 3-D position of the tip electrode relative to a surface reference electrode is then calculated: first, the amplitudes at the catheter tip due to the three orthogonal electric fields are measured relative to the surface reference electrode; then these three amplitudes are divided by their corresponding electrical field strength (as calculated during calibration).

LocaLisa has a significant advantage over competing systems that it requires no special catheters. It also reduces the patient and operator exposure to radiation during mapping. [16] However, stability of the surface reference electrode is vital to the accuracy of the system. Furthermore, this method falsely assumes a homogenous 3D electrical field within the entire body cavity. Consequently, errors at positions more than a few centimeters from the location of calibration may be on the order of 8 mm. The severity of these errors, and the measurement of the catheter position in co-ordinates relative to a reference point, prevents the positional data from being superimposed on a detailed image of the surgical region.

Therefore there is a clear need for a novel localization technology that takes advantage of the many imaging modalities that are now available (such as MRI or CT or ultrasound). The present invention is able to localize an object within the body with respect to a three-dimensional, high resolution image acquired using one or more of these modalities. This technology is also able to track the location of the object as it is moved. The high-resolution image may be acquired before the start of the medical procedure, outside the operating room. Therefore, the use of limited hospital resources and the cost of the procedure will be significantly reduced. Furthermore, the space available to the surgical team will not be limited by the presence of bulky MRI equipment. In addition, this novel invention is safe to both patient and doctor, utilizes no special (and expensive) catheter equipment, and has high accuracy regardless of object location. As such, it promises a significant advancement in the field of localization and guidance technology, with applications across a wide range of surgical and diagnostic procedures.

### SUMMARY OF THE INVENTION

The method and apparatus of this invention permits one to localize an object within the body with respect to a high resolution image of the region of the body.

According to a first aspect, the method of the invention for localizing an object in the body includes obtaining an image of a region of the body. This image is then used to estimate the electrical conductivity at a plurality of locations. A plurality of Body Electrodes are then applied to the body, and one or more objects containing one or more conducting Object Electrodes are introduced into the region of the body that was imaged. Electrical currents are then applied to the Body Electrodes and the electrical activity that results within the body is detected by the Object Electrodes and recorded. The recorded electrical activity is then used to estimate the locations of the one or more Object Electrodes. In a preferred embodiment, MRI or CT or ultrasound is used to obtain images of the region of a body. Subsequently, the electrical conductivity at a plurality of locations within this region of the body may be estimated by segmenting the images into tissue types and assigning conductivity values to each tissue-type. Alternately, the electrical conductivity at a plurality of locations within this region of the body may be estimated by correlating a characteristic of the image signal from each location with the conductivity of that location. The image signal, for example, might be the intensity of the signal in the case of ultrasound, relaxation time in the case of MRI, or x-ray density in the case of CT.

In a preferred embodiment, the electrical activity due to currents consecutively injected by the Body Electrodes is simulated at a plurality of locations. This simulated activity may then be stored. In one embodiment, the simulated electrical activity at a plurality of locations is compared with the electrical activity detected by the one or more Object Electrodes; the location with the ‘most similar’ simulated electrical activity to that detected by the one or more Object Electrodes may then be defined as the location of the Object Electrode. In a preferred embodiment of this invention, knowledge of the electrical activity detected by the one or more Object Electrodes is used to improve the accuracy of the simulation.

In another preferred embodiment, the locations of the one or more Object Electrodes are displayed on a graphical user interface. The displayed locations of the one or more Object Electrodes may be superimposed on an image of a region of the body. In another preferred embodiment, the object is repeatedly localized as the object is moved within the body.

According to a second aspect, the method of the invention for localizing an object in the body includes applying a plurality of electrodes to the body (Body Electrodes). An object containing one or more conducting electrodes (Object Electrodes) is then introduced into the body. Electrical currents with a frequency greater than 50 KHz (so as to reduce the electrical anisotropy of body tissues) are applied to the Body Electrodes and the electrical activity detected by the Object Electrodes is recorded. The locations of one or more Object Electrodes are then estimated using the recorded electrical activity.

### BRIEF DESCRIPTION OF THE DRAWING

FIG. 1 is a flow chart of the method for localizing an object inside the body.

FIG. 2 is a flow chart of a preferred embodiment of the method for localizing an object inside the body.

FIG. 3 is a schematic diagram of an apparatus for localizing an object inside the body.

FIG. 4 shows a simulation model that demonstrates a simple example of our method to localize an object in the volume conductor.

FIG. 5 shows a horizontal (x-y) slice through the center of the simulated model, with the simulated voltage values for the voxels within that slice displayed on the z-axis.

FIG. 6 is a flow chart of the method for localizing an object inside the body when the electrical currents that are applied to the Body Electrodes have a frequency of greater than 50 kHz.

### DESCRIPTION OF THE PREFERRED EMBODIMENTS

In order to guide a surgical instrument to the surgical target, it may be sufficient to know the locations of the instrument and target relative to a fixed reference point. However, in order to display their locations within a high-resolution anatomical image of the surgical area (such as an MRI image) we must know their absolute positions. The ability to locate a surgical instrument within an detailed image of the surgical region may be highly useful: the target may be a precise anatomical location; the risk of a surgical mistake (for instance, in the heart, puncture of the myocardial wall leading to tamponade) is highly diminished; and the surgeon may simply feel more comfortable guiding the instrument if such images are available. This ability is provided by our current innovation.

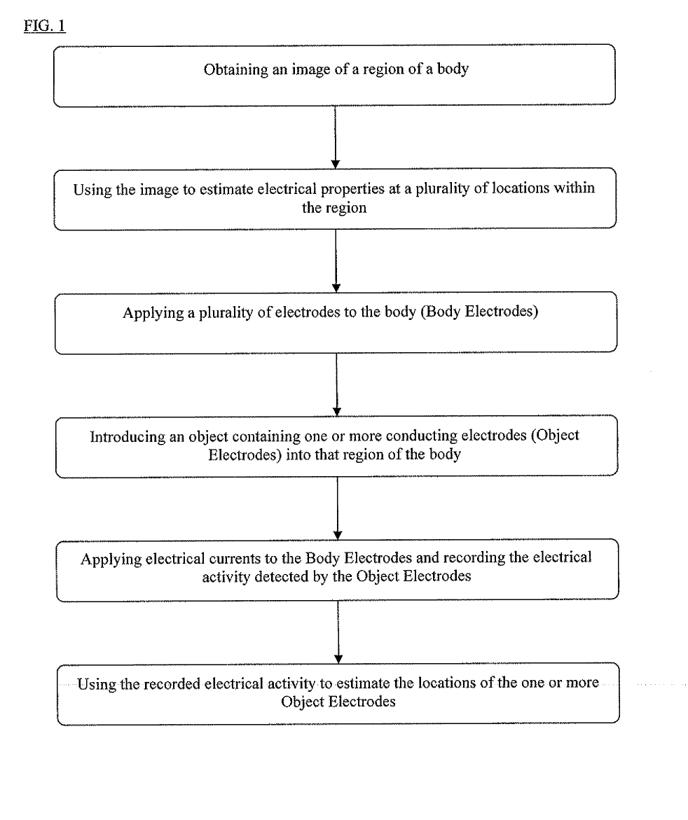

FIG. 1 shows a flowchart of the method according to the present invention of localizing an object inside the body. The method includes obtaining an image of a region of the body. This image is then used to estimate the electrical conductivity at a plurality of locations. A plurality of Body Electrodes are then applied to the body, and one or more objects containing one or more conducting Object Electrodes are introduced into the region of the body that was imaged. Electrical currents are then applied to the Body Electrodes and the electrical activity that results within the body is detected by the Object Electrodes and recorded. The recorded electrical activity is then used to estimate the locations of the one or more Object Electrodes.

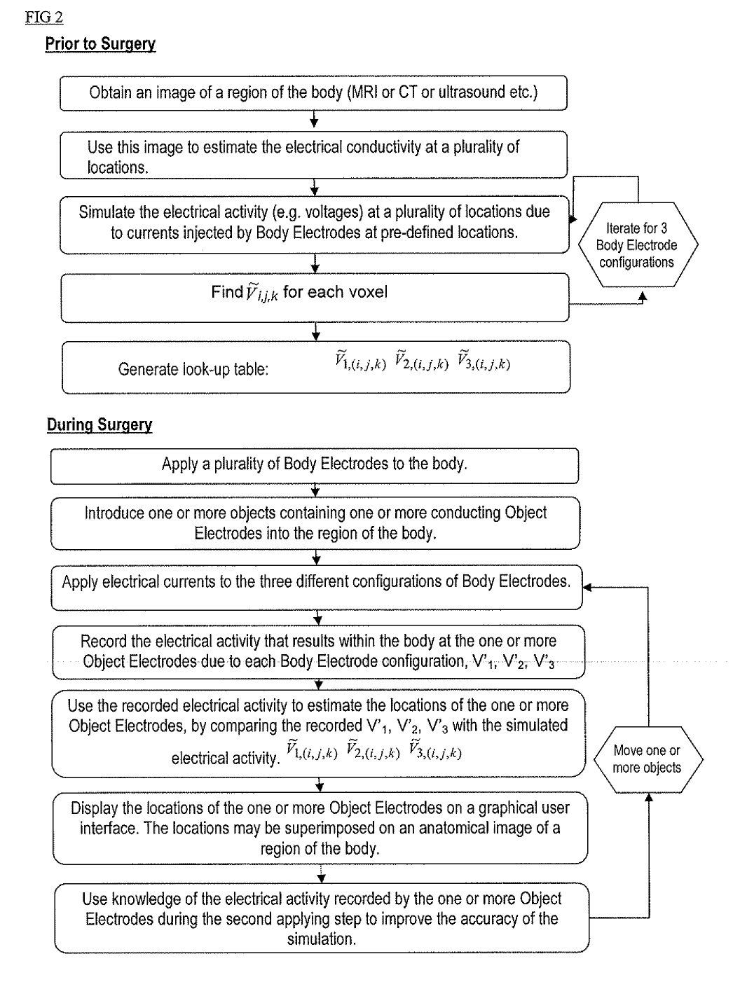

FIG. 2 shows a flowchart of a preferred embodiment of the method according to the present invention of localizing an object inside the body. In a preferred embodiment, before the surgical procedure begins, MRI or CT or ultrasound is used to obtain images of the region of a body. The images encompass the surgical area of interest, and may provide full cross-sectional views of the region of the body. Images may be taken with a resolution on the order of 2 mm, so that each image ‘voxel’ is of dimension 2×2×2 mm; this figure is provided for the sake of illustration and is not intended to limit the scope of this disclosure.

Subsequently, the electrical conductivity at a plurality of locations within this region of the body may be estimated. In a preferred embodiment, the anatomical images are processed to obtain an electrical conductivity value (Ω⁻¹cm⁻¹) for each location. A ‘conductivity map’ of the surgical area of interest is thus generated.

There are two methods that we may explore by which to assign an accurate conductivity value to each location. In a preferred embodiment, a location's conductivity value is determined primarily by the body tissue in which it is located. Therefore conductivity maps may be obtained by segmentation of the anatomical images into tissue types and subsequent assignment of conductivities from published values. [17] Currently available segmentation software is either semi- or full-automatic. [18] While this method is fairly straight-forward, it does not account for variation of a given tissue between individuals or for conductivity changes within the same tissue. [19] Furthermore, partial-volume effects (that occur when multiple tissue types contribute to the same voxel) may lead to ambiguities in tissue-type assignment. Finally, some tissue types have a wide range of published conductivities possibly due to differences in hydration, individual variation in the properties of a given tissue, or measurement inaccuracies. Significant errors in the conductivity map may result if the wrong values are applied.

Alternatively, the anatomical images may be converted directly into a conductivity map. In one preferred embodiment, the images acquired using MRI are converted directly into a conductivity map. The intensity of a single pixel is dependent on both T1, the spin-lattice relaxation time, and T2, the spin-spin relaxation time. Since T1 is related to water content, if the contribution of T1 to the signal intensity is isolated (by using methods such as those proposed by Mazzurana et al) we may determine the water content of each voxel. [20] The conductivity of each voxel may then be determined from its water content using published methods. [21] Fat and cortical bone generate significant contrast despite their low water permittivity values. Consequently, a suitable method (such as that proposed by Bondestam et al [22]) must be used to segment these tissues from MRI images and assign appropriate values from published data. Obstacles to the direct conversion of MRI image intensities into conductivities include ‘intensity inhomogeneities’, which result from limitations in scanner equipment and cause a shading effect to appear over an image. Furthermore, fat and cortical bone tissues must still be segmented. However, conductivities assigned in this fashion have been shown to be in reasonable agreement with published values and this method may provide the most rapid and reliable tool for generating conductivity maps. [20]

In another preferred embodiment, the patient's CT scans may be converted directly into a conductivity map. X-ray absorption is correlated with the density of the tissue through which the X-ray has passed. Consequently, more dense tissues such as bone appear white, whereas less dense tissues such as the heart appear in shades of gray, and air-filled sacs within the lung appear almost black. A conductivity value for each pixel may be retrieved from its corresponding tissue density value.

In another preferred embodiment, the patient's ultrasound scans may be converted directly into a conductivity map. The grayscale value of an ultrasound image pixel depends on the intensity of the signal reflection from that pixel. Pixels corresponding to an interface between tissues with significantly different abilities to transmit sound will appear bright on the ultrasound image. On the other hand, pixels corresponding to an area of general homogeneity will be dark. Since different tissues are characterized by different inhomogeneities, they will each scatter differently; it may be possible to use the resulting signal intensity to assign pixel conductivities automatically.

In another preferred embodiment the two methods for creating conductivity maps are combined by using margins around published values to constrain the tissue conductivity we estimate from the image signal. As is evident, there are several possible methods to generate voxel conductivity maps. These three methods are described here for the sake of illustration and are not intended to limit the scope of this invention.

In a preferred embodiment, the electrical activity due to currents consecutively injected by the Body Electrodes is then simulated at a plurality of locations. A set of two Body Electrodes is simulated to lie at pre-defined locations on the body, and the potentials that would result inside the region of the body from current flow between them are modeled. The current flow at each location must be calculated in order to determine the potential at each location. Current flows under the current electrodes are well-defined. For all other locations within the torso, which are by definition neither current sources nor sinks, we base our method on the relationship between the current density within an enclosed surface (J), the electrical conductivity within the enclosed surface (σ), and the potential gradient across the surface (Φ):

$$J = σ \cdot ∇ φ \\ ∇ \cdot J = ∇ \cdot ( - σ \cdot ∇ φ ) = 0 \\ {∇}^{2} φ + \frac{∇ φ \cdot ∇ σ}{σ} = {∇}^{2} φ + ∇ φ \cdot ln ( ∇ σ ) = 0 \qquad ( Eqn . 1 )$$

Since boundary conditions prohibit current flow out of the body, current flow orthogonal to the surface is zero at locations at the torso boundaries.

Next, we assume conductivity is defined at the center of each voxel and that ln(σ) varies linearly between each center. We may then solve Eqn 1 by solving for the potential of each voxel (φ₀) as a weighted sum of the potentials of its surrounding voxels (φᵢ):

$${ϕ}_{0} = \frac{{\sum }_{i = 1}^{6} {w}_{i} \cdot {ϕ}_{i}}{{\sum }_{i} {w}_{i}} \qquad ( Eqn . 2 )$$

where wᵢ is defined as:

$${w}_{i} = \frac{{r}_{i} ln ( {r}_{i} )}{( {r}_{i} - 1 )} and \\ {r}_{i} = \frac{{σ}_{i}}{{σ}_{0}} \qquad ( Eqn . 3 a )$$

If we assume σ varies linearly between each center, wᵢ is instead defined as:

$${w}_{i} = \frac{{r}_{i} - 1}{ln ( {r}_{i} )} \qquad ( Eqn . 3 b )$$

To reduce computation time, the torso volume may be initially partitioned into a coarse grid of volume elements of dimension greater than 1 cm. The conductivity of each volume element is approximated by averaging the conductivities of all the locations contained within it. The potentials at the centers of every volume element are then calculated in parallel using Eqns. 2 and 3, and these calculations are iterated on until the potentials converge to a pre-defined end-point. Following convergence for the coarsest grid, the volume element size may be halved in each dimension, and the potentials from the coarser grid ‘projected’ onto the finer grid. The potentials at this finer resolution are then iterated on until they converge, the grid dimensions are halved, and so on, until the resolution of the calculations is the same as the resolution of the anatomical images taken.

The voxel potentials are simulated for three different locations of the surface electrodes. Following these simulations, each location within the MRI image is defined by a unique ‘voltage triplet’, in which each member of the triplet is the voxel potential resulting from the flow of current between the electrodes in one set. In another preferred embodiment, this simulated activity is saved (for instance, in the form of a ‘look-up table’).

At the start of the surgical procedure, Body Electrodes with skin-contact dimensions that would ideally be on the order of the resolution of the anatomical image are placed at the locations used in the simulations, and the surgical instrument is inserted subcutaneously. In one embodiment, the simulated electrical activity at a plurality of locations is compared with the electrical activity detected by the one or more Object Electrodes. The location with the ‘most similar’ simulated electrical activity to that detected by each Object Electrode may then be defined as the location of that Object Electrode. By finding the unique voltage triplet stored in the look-up table that is most similar to the potentials measured at the instrument tip, the instrument location may be identified in real-time. ‘Similarity’ may be assessed using one or more measures that compare the recorded electrical activity to the simulated electrical activity.

In a preferred embodiment of this invention, knowledge of the electrical activity detected by the one or more Object Electrodes is used to improve the accuracy of the simulation. The method's accuracy relies on the accurate simulation of electrical activity in a region of the body, such that the measured electrical activity at any location will be highly similar to the simulated electrical activity at that location. However, small inaccuracies in the assigned conductivity values and limitations in the current flow model may lead to sub-optimal look up table accuracy. Following object insertion, as the object is moved through the region of the body knowledge of the electrical activity detected by the one or more Object Electrodes may be recorded and used to improve the accuracy of the simulation.

In another preferred embodiment, the locations of the one or more Object Electrodes are displayed on a graphical user interface. The displayed locations of the one or more Object Electrodes may be superimposed on an image of a region of the body. The ability to superimpose object locations on a high-resolution, detailed anatomical map of the region of the body is one of the great advantages of the current invention.

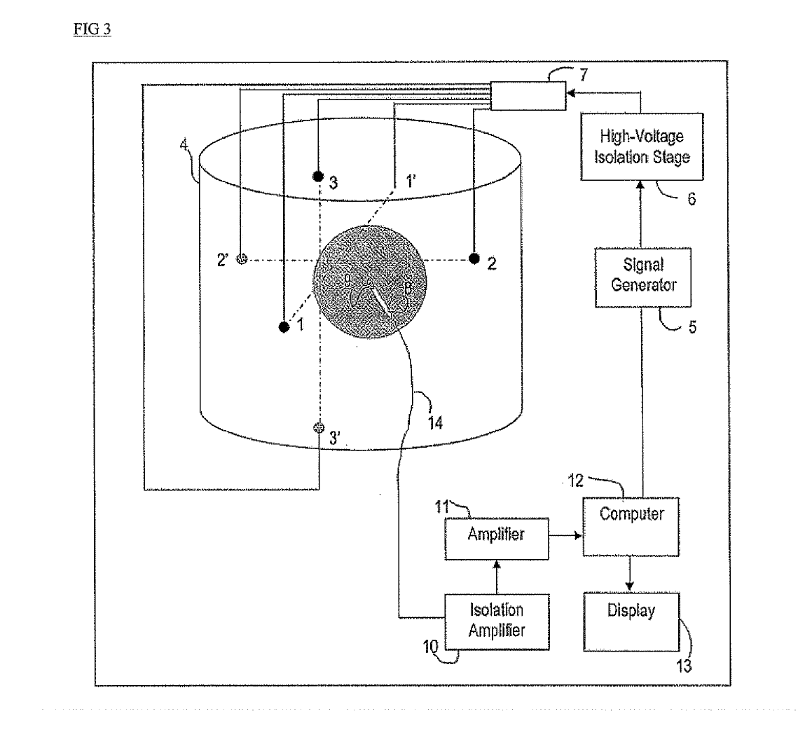

FIG. 3 shows a preferred embodiment of the apparatus for localizing an object inside the body, after an image has been taken of the region of the body, the regional electrical conductivity has been approximated, and the regional electrical activity has been calculated. A plurality of Body Electrode pairs (1 and 1′, 2 and 2′, 3 and 3′) are placed on a region of the body 4 such that the region of the body may be viewed from several sides, and in the same locations as those used in the simulations of electrical activity. The Body Electrodes need not be arrayed such that the signals between each pair are orthogonal. Each electrode position is provided by the operator to the analysis software. The Body Electrodes are connected via a multi-lead cable 7 through a high-voltage isolation stage 6 to a signal generator 5, which is controlled by a computer 12 and can generate currents between each of the Body Electrode pairs in turn. The current magnitude should be of sufficient amplitude to create a significant potential gradient across the region of the body, but of small enough amplitude to be safe to apply to the patient (e.g. 1 mA).

Signals from the one or more Object Electrodes 9 on the object 8 are carried in a cable 14 through an isolation amplifier 10 to an amplifier 11 with adjustable gain and frequency response. The computer 12 equipped with an analog to digital conversion card digitizes, processes and records the signals detected by the Object Electrodes. As described in detail above, in a preferred embodiment of the invention, the location of the Object is found by comparing the signals detected by the Object Electrodes with the simulated electrical activity at a plurality of locations. The location with the ‘most similar’ simulated electrical activity to that detected by each Object Electrode may then be defined as the location of that Object Electrode. The computer 12 then displays the calculated location of the Object Electrode on a display 13. The displayed locations of the one or more Object Electrodes may be superimposed on a displayed image of the region of the body.

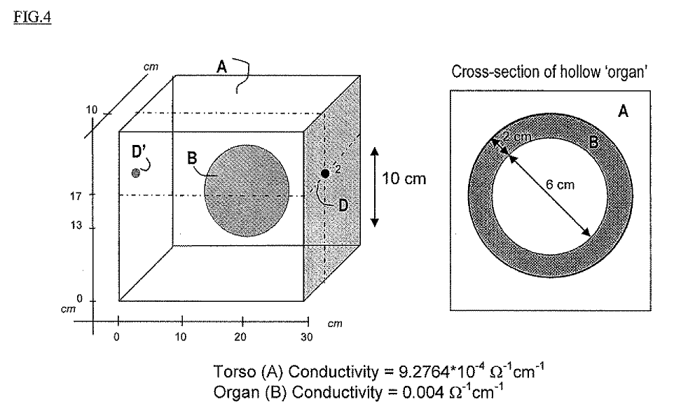

FIG. 4 shows a simulation model that demonstrates a simple example of our method to localize an object in the volume conductor. The volume conductor A is modeled here as a homogenous cube, containing a spherical hollow ‘organ’ B of a different conductivity centered in the middle of the cube (a cross-section of the hollow organ is also provided in FIG. 4). The conductivity of the homogenous cube was chosen to be 0.001Ω⁻¹cm⁻¹ and the conductivity of the spherical organ was 0.004Ω⁻¹cm⁻¹. Body Electrodes were simulated at six locations on the volume conductor surface. A current of 1 mA was applied through each pair of the simulated Body Electrodes in turn.

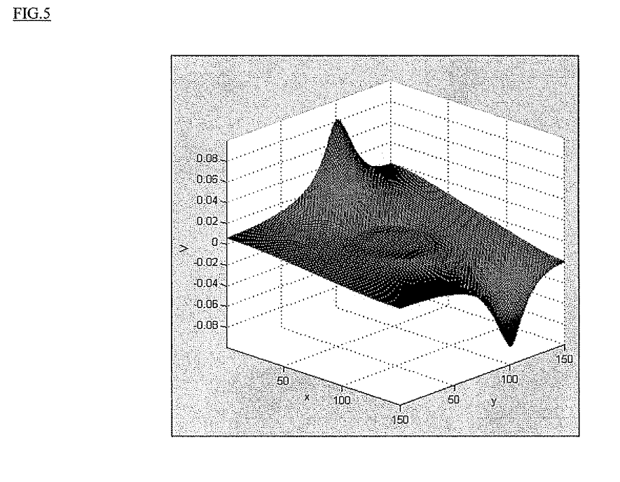

One set of Body Electrodes (D and D′) is shown in FIG. 4. The simulated voltages for this pair of surface Body Electrodes is shown in FIG. 5. The figure shows a horizontal (x-y) slice through the center of the volume conductor, with the simulated voltage values for the voxels within that slice displayed on the z-axis. It has been found using this and other volume conductor models that each voxel in a region of the volume conductor (for instance within the hollow spherical organ in FIG. 3) is defined by a unique set of voltages if three or more injected currents are used.

To examine the effect of noise on our ability to uniquely identify a voxel by its three voltage values, we defined the Euclidean distance, E_{V}, between the potentials of two voxels i and j to be:

E_{V}=\sqrt{(Vᵢ₁−Vⱼ₁)²+(Vᵢ₂+Vⱼ₂)²+(Vᵢ₃−Vⱼ₃)²} (Eqn. 4)

where Vᵢ₁ is the potential of voxel i due to Body Electrode pair 1, Vᵢ₂ is the potential of voxel i due to Body Electrode pair 2, etc. Using the model in FIG. 4, with voxel dimensions of 2 mm on a side, neighboring voxels within the simulated hollow organ were found to be distinguishable from each other by a minimum Euclidean distance of 40 μV. The noise expected in a hospital setting in the frequency range of 10-20 kHz is on the order of 10 μV or less. Furthermore, environmental shielding is a possibility for frequencies in the range of 10 kHz. Consequently, even in the presence of the noise expected in a hospital environment, each voxel should have a uniquely identifiable voltage triplet. We should therefore be able to resolve the position of the catheter tip to the same resolution as the anatomical image (i.e. 2 mm or less).

The invention's method to simulated current flow has also been tested by simulating the ‘four electrode technique’. This technique has been used in many studies to measure the conductivity of excised tissue. [23-27] When alternating current is passed between two electrodes placed on the surface of a tissue, frequency-dependent polarization generates a counter voltage at the electrode tips. Consequently, the resistance measured between the electrodes reflects not only the tissue but also the electrode-tissue interface. The effect of the interface is removed by using four electrodes arranged so that their tips touch the tissue at four equally spaced points along a straight line: two outer electrodes for current injection, and two inner electrodes for voltage measurement. Needle electrodes are used so that a point-source approximation can be made. For a homogenous tissue, the voltage difference measured is related to the tissue conductivity by a well established relationship. If the tissue is homogenous and its dimensions are large enough such that boundary effects are negligible, the tissue's conductivity can be estimated from the measured voltage difference by a well-established relationship.

$${σ}_{calc} = \frac{I}{2 π d Δ V} \qquad ( Eqn . 5 )$$

where ΔV is the voltage difference, σ_{calc} is the tissue conductivity between the electrodes, I is the current injected, and d is the distance between two adjacent electrodes. Therefore, one measure of the ability of the present invention to simulate a realistic experimental setting is how similar the value of σ_{calc} is to the actual value of σ for a simulated homogenous model. The present invention has been found to produce values of σ_{calc} less than 0.1% different from the actual value. This is a highly successful preliminary test of the accuracy of our current flow model. Therefore, testing has indicated that the present invention may be used to localize an object inside a region of the body in real-time and with high accuracy.

The present invention differs significantly from the LocaLisa positioning system. Localisa is a non-fluoroscopic catheter positioning system that allows a conventional catheter to be located within the heart in three dimensions. It utilizes three orthogonal (or nearly-orthogonal) electric fields, generated across the body by sets of skin electrodes. For calibration purposes, Localisa calculates the electrical field strength due to each applied current within the cardiac chamber of interest, assuming that the electrical field due to the applied current is constant across the body (and especially within the chamber of interest). The 3-D position of the tip electrode relative to a surface reference electrode is then calculated, by first measuring the amplitudes at the catheter tip relative to a surface reference electrode due to the three orthogonal electric fields, and then dividing these three amplitudes by the corresponding electrical field strengths (calculated during calibration). In significant contrast to the present invention, torso inhomogeneities are not taken into account, no conductivity map is generated, and electrical activity due to the applied currents is not simulated. This leads to substantial degradation in accuracy of localization and overall performance of the system. Furthermore, near-orthogonality of the applied currents is crucial to Localisa's accuracy. In contrast, the present invention places no such restriction on the placement of the surface electrodes.

Stability of the surface reference electrode is also vital to the accuracy of the Localisa system; the present invention utilizes no such reference and so does not suffer from this drawback. Furthermore, because this method falsely assumes a homogenous 3D electrical field within the entire body cavity, errors at positions more than a few centimeters from the location of calibration may be on the order of 8 mm. The severity of these errors, and the measurement of the catheter position in co-ordinates relative to a reference point, prevents the positional data from being superimposed on a detailed image of the surgical region. The present invention, on the other hand, will yield a much higher accuracy and allow superposition of an image of the surgical instrument onto a high-resolution image of the surgical region. Consequently, although both Localisa and the present invention require the injection of currents by surface electrodes to image the location of the surgical instrument, they differ significantly in the requirements placed on the system, in how the applied currents are used to calculate the instrument location, in the accuracy of the calculated location, and in the presentation of the information.

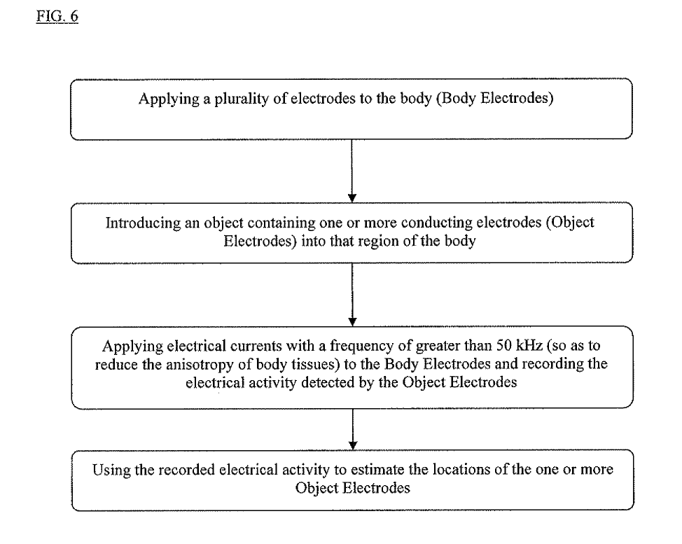

FIG. 6 shows a flowchart of the method according to the present invention of localizing an object inside the body when the frequency of the current applied to the Body Electrodes is greater than 50 kHz. The method includes applying a plurality of Body Electrodes to the body, and introducing one or more objects containing one or more conducting Object Electrodes into the region of the body. Electrical currents with a frequency of greater than 50 kHz (so as to reduce the anisotropy of body tissues) are then applied to the Body Electrodes and the electrical activity that results within the body is detected by the Object Electrodes and recorded. The recorded electrical activity is then used to estimate the locations of the one or more Object Electrodes.

The anisotropy of the electrical properties, such as electrical conductivity, of body tissues can reduce the accuracy of the localization if not compensated for. In one preferred embodiment the anisotropy of electrical properties of various tissues is explicitly accounted for in calculating the simulated electrical activity. In another preferred embodiment the frequency of the applied electrical currents is elevated above 50 kHz in order to reduce the magnitude of the anisotropy of the electrical properties of various tissues.[28] It has not been previously appreciated that the accuracy of electrical localization methods can be improved by reducing the anisotropy of the electrical properties of body tissues by means of applying currents above 50 KHz. Traditionally frequencies in the range of 10 to 30 kHz have been utilized.

It is recognized that modifications and variations of the present invention will occur to those skilled in the art, and it is intended that all such modifications and variations be included within the scope of the appended claims.

### REFERENCES

[1] M. J. Mack, “Minimally invasive and robotic surgery,” Jama, vol. 285, pp. 568-72, 2001.
[2]H. C. Jacobaeus, “Possibility of the use of a cystoscope for investigation of serous cavities,” Munch Med Wochenschr, vol. 57, pp. 2090-2092, 1910.
[3] C. J. Davis, “A history of endoscopic surgery,” Surg Laparosc Endosc, vol. 2, pp. 16-23, 1992.
[4]H. Calkins, L. Niklason, J. Sousa, R. el-Atassi, J. Langberg, and F. Morady, “Radiation exposure during radiofrequency catheter ablation of accessory atrioventricular connections,” Circulation, vol. 84, pp. 2376-82, 1991.
[5] E. B. van de Kraats, T. van Walsum, L. Kendrick, N. J. Noordhoek, and W. J. Niessen, “Accuracy evaluation of direct navigation with an isocentric 3D rotational X-ray system,” Med Image Anal, vol. 10, pp. 113-24, 2006.
[6] B. D. Fomage, “Sonographically guided needle biopsy of nonpalpable breast lesions,” J Clin Ultrasound, vol. 27, pp. 385-98, 1999.
[7] V. Velanovich, F. R. Lewis, Jr., S. D. Nathanson, V. F. Strand, G. B. Talpos, S. Bhandarkar, R. Elkus, W. Szymanski, and J. J. Ferrara, “Comparison of mammographically guided breast biopsy techniques,” Ann Surg, vol. 229, pp. 625-30; discussion 630-3, 1999.
[8] J. U. Blohmer, R. Bollmann, G. Heinrich, S. Paepke, and W. Lichtenegger, “[Three-dimensional ultrasound study (3-D sonography) of the female breast],” Geburtshilfe Frauenheilkd, vol. 56, pp. 161-5, 1996.
[9] M. Kriege, C. T. Brekelmans, C. Boetes, P. E. Besnard, H. M. Zonderland, I. M. Obdeijn, R. A. Manoliu, T. Kok, H. Peterse, M. M. Tilanus-Linthorst, S. H. Muller, S. Meijer, J. C. Oosterwijk, L. V. Beex, R. A. Tollenaar, H. J. de Koning, E. J. Rutgers, and J. G. Klijn, “Efficacy of MRI and mammography for breast-cancer screening in women with a familial or genetic predisposition,” N Engl J Med, vol. 351, pp. 427-37, 2004.
[10] R. Sequeiros, Ojala, R, Perala, J, Tervonen, 0, “MR-Guided Interventional Procedures: A Review,” ACTA Radiologica, vol. 6, pp. 576-586, 2005.
[11]H. Wright, J. Listinsky, A. Rim, M. Chellman-Jeffers, R. Patrick, L. Rybicki, J. Kim, and J. Crowe, “Magnetic resonance imaging as a diagnostic tool for breast cancer in premenopausal women,” Am J Surg, vol. 190, pp. 572-5, 2005.
[12] M. Cristofanilli, “The role of magnetic resonance imaging as an imaging tool to assess disease status and residual disease in locally advanced breast cancer,” presented at Madrid Breast Cancer Conference, Madrid, Spain, 2005.
[13] J. Dong, H. Calkins, S. B. Solomon, A. Lardo, E. Brem, R. D. Berger, H. Halperin, and T. Dickfeld, “Accuracy of a novel image integration technique for real-time guided ablation procedures on computed tomographic images,” Circulation, vol. 112, pp. U34-U34, 2005.
[14] A. Gupta, Maheshwari, A, Thakur, R. et al., “Catheter Ablation of Atrial Tachycardia using a Real-Time Position Management Mapping System,” Indian Heart Journal, vol. 55, pp. 75-77, 2003.
[15] F. H. Wittkampf, E. F. Wever, R. Derksen, A. A. Wilde, H. Ramanna, R. N. Hauer, and E. O. Robles de Medina, “LocaLisa: new technique for real-time 3-dimensional localization of regular intracardiac electrodes,” Circulation, vol. 99, pp. 1312-7, 1999.
[16] V. Markides and D. W. Davies, “New mapping technologies: an overview with a clinical perspective,” J Interv Card Electrophysiol, vol. 13 Suppl 1, pp. 43-51, 2005.
[17] P. J. Dimbylow and S. M. Mann, “SAR calculations in an anatomically realistic model of the head for mobile communication transceivers at 900 MHz and 1.8 GHz,” Phys Med Biol, vol. 39, pp. 1537-53, 1994.
[18] D. L. Pham, C. Xu, and J. L. Prince, “Current methods in medical image segmentation,” Annu Rev Biomed Eng, vol. 2, pp. 315-37, 2000.
[19] P. Farace, R. Pontalti, L. Cristoforetti, R. Antolini, and M. Scarpa, “An automated method for mapping human tissue permittivities by MRI in hyperthermia treatment planning,” Phys Med Biol, vol. 42, pp. 2159-74, 1997.
[20] M. Mazzurana, L. Sandrini, A. Vaccari, C. Malacarne, L. Cristoforetti, and R. Pontalti, “A semi-automatic method for developing an anthropomorphic numerical model of dielectric anatomy by MRI,” Phys Med Biol, vol. 48, pp. 3157-70, 2003.
[21] S. R. Smith and K. R. Foster, “Dielectric properties of low-water-content tissues,” Phys Med Biol, vol. 30, pp. 965-73, 1985.
[22] S. Bondestam, A. Lamminen, M. Komu, V. P. Poutanen, A. Alanen, and J. Halavaara, “Tissue characterization by image processing subtraction: windowing of specific T1 values,” Magn Reson Imaging, vol. 10, pp. 989-95, 1992.
[23] W. Breckon, “The Problem of Anisotropy in Electrical Impedance Tomography,” EIT Research Group, Oxford Polytechnic, Oxford 1989.
[24] B. H. Brown, T. Karatzas, R. Nakielny, and R. G. Clarke, “Determination of upper arm muscle and fat areas using electrical impedance measurements,” Clin Phys Physiol Meas, vol. 9, pp. 47-55, 1988.
[25]H. C. Burger and D. van, “Specific electric resistance of body tissues,” Phys Med Biol, vol. 5, pp. 431-47, 1961.
[26] S. Rush, J. A. Abildskov, and McFeer, “Resistivity of body tissues at low frequencies,” Circ Res, vol. 12, pp. 40-50, 1963.
[27] P. Steendijk, G. Mur, E. T. Van Der Velde, and J. Baan, “The four-electrode resistivity technique in anisotropic media: theoretical analysis and application on myocardial tissue in vivo,” IEEE Trans Biomed Eng, vol. 40, pp. 1138-48, 1993.
[28] S. Gabriel, R. W. Lau, and C. Gabriel, “The dielectric properties of biological tissues: II. Measurements in the frequency range 10 Hz to 20 GHz,” Phys Med Biol, vol. 41, pp. 2251-69, 1996.

1. A method of localizing an object in the body comprising:
Obtaining an image of a region of a body;
Estimating the electrical properties at a plurality of locations within the region using the image;
Applying a plurality of electrodes to the body (Body Electrodes);
Introducing an object containing one or more conducting electrodes (Object Electrodes) into that region of the body;
Applying electrical currents to the Body Electrodes and recording the electrical activity detected by the Object Electrodes;
Estimating the locations of one or more Object Electrodes using the recorded electrical activity.

2. The method of claim 1 wherein the obtaining step includes using magnetic resonance imaging (MRI) or X-Ray Computed Tomography (CT) or ultrasound to obtain images of a region of a body.

3. The method of claim 1 wherein the electrical properties are the electrical conductivities.

4. The method of claim 1 wherein the first estimating step comprises estimating the electrical properties at a plurality of locations within a region of the body by segmenting the images into tissue types and assigning conductivity values to each tissue-type.

5. The method of claim 1 wherein the first estimating step comprises estimating the electrical properties at a plurality of locations within a region of the body by correlating a characteristic of the image signal from each location with its electrical properties.

6. The method of claim 1 further comprising simulating at a plurality of locations the electrical activity due to currents injected by the Body Electrodes.

7. The method of claim 6 further comprising storing the simulated electrical activity at a plurality of locations.

8. The method of claim 6 wherein the simulated electrical activity is a set of voltages.

9. The method of claim 1 wherein the second estimating step comprises comparing the simulated electrical activity at a plurality of locations with the electrical activity detected by the one or more Object Electrodes during the second applying step.

10. The method of claim 1 wherein the second estimating step includes using knowledge of the electrical activity detected by the one or more Object Electrodes during the second applying step to improve the accuracy of the simulation.

11. The method of claim 1 wherein the second estimating step comprises determining the location of the Object Electrode to be a location with similar simulated electrical activity to the electrical activity detected by the one or more Object Electrodes during the second applying step.

12. The method of claim 1 wherein the second estimating step includes displaying the locations of the one or more Object Electrodes on a graphical user interface.

13. The method of claim 10 wherein the displayed locations of the one or more Object Electrodes are superimposed on the image of a region of the body.

14. The method of claim 1 further comprising the repeated localizing of the object as the object is moved within the body.

15. The method of claim 1 further comprising accounting for the anisotropy of electrical conductivity of various tissues in the second estimating step.

16. A method for localizing an object in the body comprising:
Applying a plurality of electrodes to the body (Body Electrodes);
Introducing an object containing one or more conducting electrodes into the body (Object Electrodes);
Applying electrical currents with a frequency greater than 50 KHz (so as to reduce the electrical anisotropy of body tissues) to the Body Electrodes and recording the electrical activity detected by the Object Electrodes;
Estimating the locations of one or more Object Electrodes using the recorded electrical activity.

17. System for localizing an object in the body comprising:
Imaging means for obtaining an image of a region of a body;
Means for estimating the electrical properties at a plurality of locations within the region using the image;
A plurality of electrodes (body electrodes) to be applied to the body;
An object containing one or more conducting electrodes (object electrodes) adapted for introduction into the region of the body;
Circuitry for applying electrical currents to the body electrodes and for recording the electrical activity detected by the object electrodes; and
Computer means for estimating the locations of the one or more object electrodes using the recorded electrical activity.

18. The system of claim 17 wherein the means for obtaining the image includes magnetic residence imaging (MRI), x-ray computed tomography (CT) or ultrasound to obtain images of the region of the body.

19. The system of claim 17 wherein the electrical properties are electrical conductivities.

20. The system of claim 17 wherein the means for estimating the electrical properties comprises estimating the electrical properties at a plurality of locations within a region of the body by segmenting images into tissue types and assigning connectivity values to each tissue type.

21. The system of claim 17 wherein the means for estimating the electrical properties comprises estimating the electrical properties at a plurality of locations within a region of the body by correlating a characteristic of the image signal from each location with its electrical properties.

22. The system of claim 17 further comprising means for simulating at a plurality locations the electrical activity due to currents injected by the body electrodes.

23. The system of claim 22 further comprising means for storing the simulated electrical activity at a plurality of locations.

24. The system of claim 22 wherein the simulated electrical activity is a set of voltages.

25. The system of claim 17 wherein the means for estimating the locations of the one or more object electrodes comprises comparing the simulated electrical activity at a plurality of locations with the electrical activity detected by the one or more object electrodes when electrical currents are applied to the body electrodes.

26. The system of claim 17 wherein the means for estimating the locations of the one or more object electrodes includes means for using knowledge of the electrical activity detected by the one or more object electrodes during the time when electrical currents are applied to the body electrodes to improve the accuracy of the simulation.

27. The system of claim 17 wherein the means for estimating the locations of the one of more object electrodes comprises means for determining the location of the object electrode to be a location with similar simulated electrical activity to the electrical activity detected by the one or more object electrodes when electrical currents are applied to the body electrodes.

28. The system of claim 17 wherein the means for estimating the locations of the one or more object electrodes includes means for displaying the locations of the one or more object electrodes on a graphical user interface.

29. The system of claim 28 wherein displayed locations of the one of more object electrodes are superimposed on the image of the region of the body.

30. The system of claim 17 further comprising repeated localization of the object as the object is moved within the body.

31. The system of claim 17 further comprising means for accounting for the anisotropy of electrical conductivity of various tissues in the means for estimating the locations of the one or more object electrodes.

32. System for localizing an object in the body comprising:
A plurality of electrodes (body electrodes) adapted for application to the body;
An object containing one or more conducting electrodes (object electrodes) adapted for introduction into the body;
Circuitry for applying electrical currents with a frequency greater then 50 KHz to the body electrodes and for recording the electrical activity detected by the object electrodes so as to reduce electrical anisotropy of body tissues; and
Computer means for estimating the locations of the one or more object electrodes using the recorded electrical activity.
